(19) United States
(12) Patent Application Publication
(10) Pub. No.: US 2008/0105912 A1
(43) Pub. Date: May 8, 2008

(54) SEMICONDUCTOR MEMORY DEVICE

(75) Inventors: Ryota Katsumata, Yokohama-shi (JP); Hideaki Aochi, Kawasaki-shi (JP); Masaru Kito, Yokohama-shi (JP); Masaru Kidoh, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/680,144

(22) Filed: Feb. 28, 2007

(30) Foreign Application Priority Data
Nov. 6, 2006 (JP) 2006-299791

(51) Int. Cl. H01L 27/108

(52) U.S. Cl. 257/301; 257/E27.084

(57) ABSTRACT

A semiconductor memory device comprises a MOSFET formed in the surface of a semiconductor substrate; and a trench capacitor provided in a trench formed in the surface of the semiconductor substrate. The MOSFET includes a gate electrode formed on a gate insulator in the surface of the semiconductor substrate, a sidewall insulator formed on a sidewall of the gate electrode, a first and a second diffusion layer formed on the surface of the semiconductor substrate sandwiching the gate electrode, a trench capacitor contact formed to connect the first diffusion layer to the trench capacitor, and a bit line contact formed to connect the second diffusion layer to a bit line. The sidewall insulator close to the first diffusion layer is formed thicker than the sidewall insulator close to the second diffusion layer.

### CROSS REFERENCE TO RELATED APPLICATION

This application is based upon and claims the benefit of priority from the prior Japanese Patent Application No. 2006-299791, filed on Nov. 6, 2006, the entire contents of which are incorporated herein by reference.

### BACKGROUND OF THE INVENTION

1. Field of the Invention

The present invention relates to a semiconductor memory device and more particularly to those suitably applicable to a DRAM (Dynamic Random Access Memory) or a DRAM embedded device with a DRAM function mounted thereon.

2. Description of the Related Art

The progression of fine patterning the DRAM increasingly narrows the gate length and device width of the transistor contained in a memory cell of the DRAM. This results in deterioration of the short channel property of the transistor, and the reduction in threshold of the transistor causes a problem associated with sub-threshold leakage.

Suppression of this problem requires an increase in does of the channel impurity to correct the threshold to a higher one. The increase in does of the channel impurity, however, causes an increase in junction leakage current and resultingly deteriorates the data retention property of the memory cell as a problem.

An improvement approach therefor is a method, which comprises opening a bit line contact hole, then implanting ions of a P-type impurity through the contact hole to increase the impurity concentration in the bit line contact to elevate the threshold, as proposed (see U.S. Pat. No. 6,967,133). In this case, there is not any increase in channel concentration in the vicinity of the diffusion layer close to the storage node, which is turned into a problem on data holding. Therefore, preventing deterioration of the data holding property and shallowing the depth of the diffusion layer close to the bit line contact can suppress the short channel effect and prevent the threshold from lowering.

In this case, however, there is an increase in well concentration in the diffusion layer underneath the bit line contact, which enhances the substrate bias effect. As a result, on “1” data write, the substrate bias effect remarkably lowers the current in the triode region of the transistor and resultingly causes a write failure as a problem.

As means for solving the above problems, there is proposed a halo ion implantation process, which executes slant ion implantation into the silicon surface toward the portion almost underneath the edge of the gate electrode (see U.S. Pat. No. 6,967,133, for example). In this case, the slant ion implantation makes it possible to suppress the elevation in well concentration in the portion almost underneath the diffusion layer and increase the channel concentration almost underneath the edge of the gate electrode. The halo ion implantation executed only into the portion close to the bit line contact makes it possible to form a concentration gradient with a higher channel concentration in the portion close to the bit line contact and a lower channel concentration in the portion close to the storage node. With this channel concentration gradient, when the diffusion layer close to the bit line contact serves as the drain, that is, on data write, the higher concentration region close to the drain easily suffers the drain electric field. To the contrary, on “1” data holding where the portion close to the storage node serves as the drain, the higher channel concentration region hardly suffers the drain electric field. As a result, the threshold when the bit line contact serves as the drain is lower than the threshold when the storage node electrode serves as the drain. Ultimately, the threshold becomes low on data write where the sub-threshold leakage is not turned into a problem while the threshold becomes high on “1” data holding where the sub-threshold leakage is turned into a problem. Thus, the data write property and the data holding property can be improved at the same time.

If a DRAM memory cell array is structured such that one bit line contact is shared between two adjacent memory cells, it is required to execute halo ion implantation only into the portion close to the bit line contact (FIG. 1). The halo ion implantation executed into the portion close to the storage node electrode increases the leakage from the diffusion layer close to the storage node and accordingly requires a cover with resist or the like. In this case, the angle of the halo ion implantation is limited from a height of the resist and an interval between adjacent gates. Thus, the gate interval narrows in accordance with shrink of the DRAM cell size, and the angle of ion implantation is required to become an angle as near as vertical to the silicon substrate. Therefore, implantation of ions into portions underneath the gate edge increasingly becomes difficult. Thus, it becomes difficult to insure a sufficiently large difference between the threshold property when the bit line contact serves as the drain and the threshold property when the storage node does.

### SUMMARY OF THE INVENTION

In a first aspect the present invention provides a semiconductor memory device, which comprises a MOSFET formed in the surface of a semiconductor substrate; and a trench capacitor provided in a trench formed in the surface of the semiconductor substrate. The MOSFET includes a gate electrode formed on a gate insulator in the surface of the semiconductor substrate, a sidewall insulator formed on a sidewall of the gate electrode, a first and a second diffusion layer formed on the surface of the semiconductor substrate sandwiching the gate electrode, a trench capacitor contact formed to connect the first diffusion layer to the trench capacitor, and a bit line contact formed to connect the second diffusion layer to a bit line. The sidewall insulator close to the first diffusion layer is formed thicker than the sidewall insulator close to the second diffusion layer.

In a second aspect the present invention provides a semiconductor memory device, which comprises a MOSFET formed in the surface of a semiconductor substrate; and a trench capacitor provided in a trench formed in the surface of the semiconductor substrate. The MOSFET includes a gate electrode formed on a gate insulator in the surface of the semiconductor substrate, a sidewall insulator formed on a sidewall of the gate electrode, a first and a second diffusion layer formed on the surface of the semiconductor substrate sandwiching the gate electrode, a trench capacitor contact formed on the surface of the semiconductor substrate to connect the first diffusion layer to the trench capacitor, and a bit line contact connected to the second diffusion layer. The bit line contact is formed of polysilicon having an impurity concentration made higher than the impurity concentration of polysilicon forming the trench capacitor contact.

In a third aspect the present invention provides a semiconductor memory device, which comprises a MOSFET formed in the surface of a semiconductor substrate; and a trench capacitor provided in a trench formed in the surface of the semiconductor substrate. The MOSFET includes a gate electrode formed on a gate insulator in the surface of the semiconductor substrate, a sidewall insulator formed on a sidewall of the gate electrode, a first and a second diffusion layer formed on the surface of the semiconductor substrate sandwiching the gate electrode, a trench capacitor contact formed on the surface of the semiconductor substrate to connect the first diffusion layer to the trench capacitor, and a bit line contact connected to the second diffusion layer. The bit line contact is formed of polysilicon having a height made higher than the height of polysilicon forming the trench capacitor contact.

### BRIEF DESCRIPTION OF THE DRAWINGS

FIG. 1 shows a cross-sectional view of a memory cell in a DRAM according to a first embodiment of the present invention.

FIG. 2A is a process diagram illustrative of a step of manufacturing the DRAM according to the first embodiment.

FIG. 2B is a process diagram illustrative of a step of manufacturing the DRAM according to the first embodiment.

FIG. 2C is a process diagram illustrative of a step of manufacturing the DRAM according to the first embodiment.

FIG. 2D is a process diagram illustrative of a step of manufacturing the DRAM according to the first embodiment.

FIG. 3A is a process diagram illustrative of a step of manufacturing the DRAM according to the first embodiment.

FIG. 3B is a process diagram illustrative of a step of manufacturing the DRAM according to the first embodiment.

FIG. 3C is a process diagram illustrative of a step of manufacturing the DRAM according to the first embodiment.

FIG. 3D is a process diagram illustrative of a step of manufacturing the DRAM according to the first embodiment.

FIG. 4 shows a cross-sectional view of a memory cell in a DRAM according to a second embodiment of the present invention.

FIG. 5A is a process diagram illustrative of a step of manufacturing the DRAM according to the second embodiment.

FIG. 5B is a process diagram illustrative of a step of manufacturing the DRAM according to the second embodiment.

FIG. 5C is a process diagram illustrative of a step of manufacturing the DRAM according to the second embodiment.

FIG. 5D is a process diagram illustrative of a step of manufacturing the DRAM according to the second embodiment.

FIG. 6A is a process diagram illustrative of a step of manufacturing the DRAM according to the second embodiment.

FIG. 6B is a process diagram illustrative of a step of manufacturing the DRAM according to the second embodiment.

FIG. 6C is a process diagram illustrative of a step of manufacturing the DRAM according to the second embodiment.

FIG. 7 shows a cross-sectional view of a memory cell in a DRAM according to a third embodiment of the present invention.

FIG. 8A is a process diagram illustrative of a step of manufacturing the DRAM according to the third embodiment.

FIG. 8B is a process diagram illustrative of a step of manufacturing the DRAM according to the third embodiment.

FIG. 8C is a process diagram illustrative of a step of manufacturing the DRAM according to the third embodiment.

FIG. 9A is a process diagram illustrative of a step of manufacturing the DRAM according to the third embodiment.

FIG. 9B is a process diagram illustrative of a step of manufacturing the DRAM according to the third embodiment.

FIG. 9C is a process diagram illustrative of a step of manufacturing the DRAM according to the third embodiment.

FIG. 10A is a process diagram illustrative of a step of manufacturing the DRAM according to the third embodiment.

FIG. 10B is a process diagram illustrative of a step of manufacturing the DRAM according to the third embodiment.

FIG. 10C is a process diagram illustrative of a step of manufacturing the DRAM according to the third embodiment.

FIG. 11 shows a cross-sectional view of a memory cell in a DRAM according to a fourth embodiment of the present invention.

FIG. 12 shows a cross-sectional view of a memory cell in a DRAM according to other embodiment of the present invention.

FIG. 13 shows a cross-sectional view of a memory cell in a DRAM according to other embodiment of the present invention.

FIG. 14 shows a cross-sectional view of a memory cell in a DRAM according to other embodiment of the present invention.

FIG. 15 shows a cross-sectional view of a memory cell in a DRAM according to other embodiment of the present invention.

FIG. 16 shows a cross-sectional view of a memory cell in a DRAM according to other embodiment of the present invention.

### DETAILED DESCRIPTION OF THE EMBODIMENTS

Semiconductor memory devices according to the present invention will now be described below with reference to the drawings.

### First Embodiment

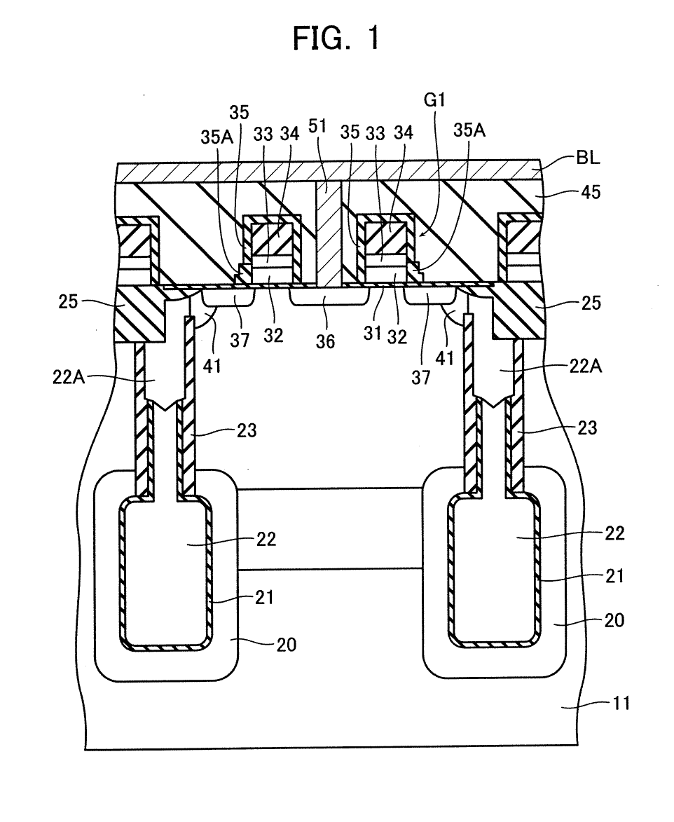

A DRAM according to a first embodiment of the present invention is described first with reference to FIG. 1. FIG. 1 shows a cross-sectional view of a memory cell in the DRAM according to this embodiment. As shown in FIG. 1, the memory cell of this embodiment is of the trench capacitor type that includes a trench formed in a p-type semiconductor substrate 11 and a capacitor (trench capacitor) formed in the trench for data holding. The trench capacitor is connected with a cell transistor (described later) to form a memory cell.

The trench capacitor includes a plate diffusion layer 20, a node insulator 21, a storage node electrode 22 and a polysilicon electrode 22A.

The plate diffusion layer 20 is formed by coating with AsSG on the trench of the semiconductor substrate 11, which has been formed in the semiconductor substrate 11, and then thermally diffusing ions of Arsenic (As). Or the plate diffusion layer 20 is formed by gas phase diffusion in PH3 atmosphere.

The node insulator 21 is formed by depositing a film of high dielectric such as Silicon nitride and Al₂O₃ on a sidewall in the trench.

The storage node electrode 22 is formed by burying polysilicon in the trench after formation of the node insulator 21. The polysilicon electrode 22A is formed by burying polysilicon in the trench on the storage node electrode 22. The polysilicon electrode 22A is connected to the cell transistor through a later-described buried strap 41 (trench capacitor contact).

On the trench sidewall is formed a collar insulator 23 composed, for example, of silicon oxide. The collar insulator 23 has a function of isolating the above-described plate diffusion layer 20 from the diffusion layer in the cell transistor. Memory cells are isolated from each other using a device isolation film 25 formed in the surface of the semiconductor substrate 11. In this embodiment, two memory cells shares a bit line contact and the device isolation film 25 is provided for the paired two memory cells as described later. The device isolation film 25 is formed by forming a trench in the surface of the semiconductor substrate 11 and burying silicon oxide in the trench using a plasma CVD process or the like.

The cell transistor, which configures a memory cell together with the trench capacitor, includes a gate insulator 31 formed on the surface of the semiconductor substrate 11 and a gate electrode G1 formed on the gate insulator 31.

The gate electrode G1 has a layered structure including a polysilicon layer 32, a WSi layer 33 serving as a word line in the DRAM, and a silicon nitride 34. On a sidewall of the gate electrode G1 is formed a sidewall insulator 35 composed of silicon oxide or the like.

On the surface of the semiconductor substrate 11 on both sides of the gate electrode G1 are formed an n-type diffusion layer 36 (the second diffusion layer) and an n-type diffusion layer 37 (the first diffusion layer), which are used for source and drain diffusion layers of the cell transistor. The n-type diffusion layer 36 is shared between two cell transistors and on the surface of the layer is formed a bit line contact 51 that is connected to a bit line BL.

On the other hand, the n-type diffusion layer 37 is connected to the storage node electrode 22 of the trench capacitor via the buried strap 41 and the polysilicon electrode 22A. The gate electrode G1 is covered in an interlayer insulator 45 and on the surface of the insulator is formed the bit line BL that is connected to the bit line contact 51.

In this embodiment, the sidewall insulator 35 is made thicker at the portion close to the trench capacitor or close to the storage node electrode 22 than the portion close to the bit line contact 51. In a word, the sidewall insulator 35 has a thick portion 35A on the side close to the storage node electrode 22 made thicker than a portion on the opposite side close to the bit line contact 51. The thick portion 35A may be formed to have a thickness of about 140 Å if the sidewall insulator 35 has a thickness of 40 Å at other portions. Because such the difference in thickness of the sidewall insulator 35 is given between the left and right sides of the gate electrode G1, the cell transistor has a lower threshold on data write while the cell transistor has a higher threshold on “1” data holding. Thus, the data write property and the data holding property can be improved at the same time.

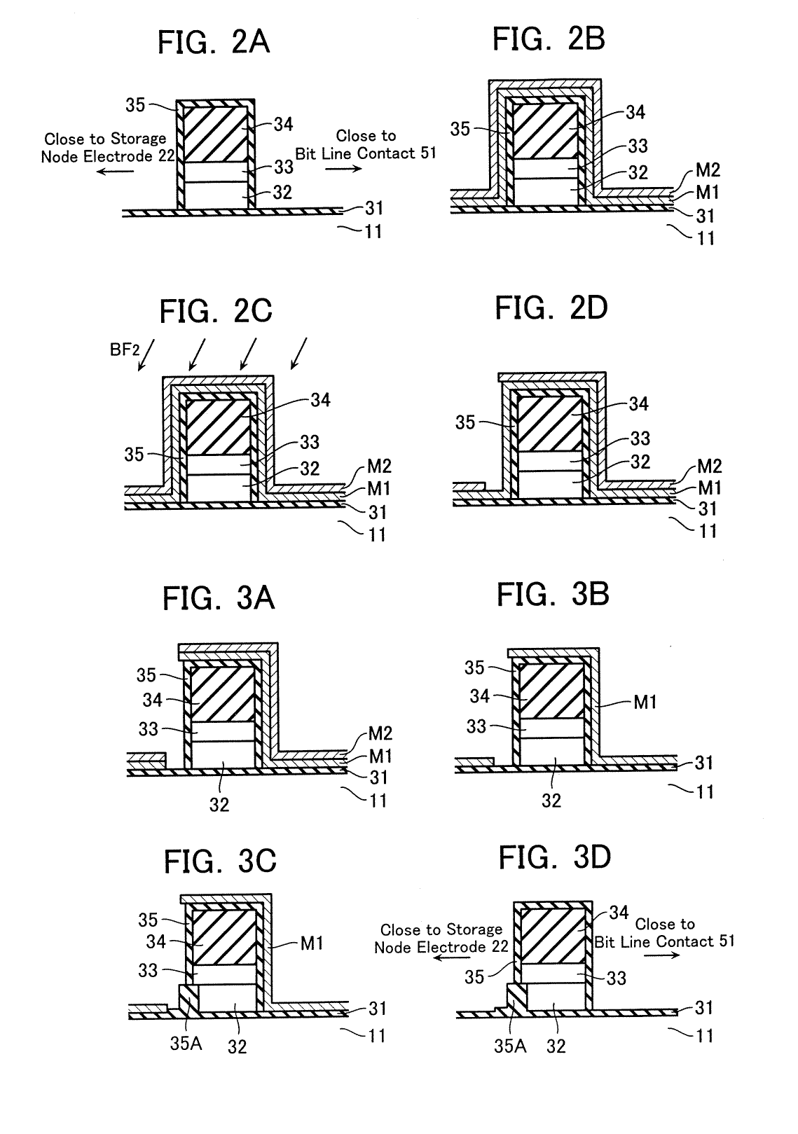

A procedure for formation of such the sidewall insulator 35 is described next with reference to FIGS. 2A-2D and FIGS. 3A-3D.

First, after processing the gate electrode G1, wet RTO (Rapid Thermal Oxidation) with a mixed gas of hydrogen and oxygen is applied under a low pressure to oxidize the sidewall of the gate electrode G1 at a thickness of 40 Å to form the sidewall insulator 35 as shown in FIG. 2A.

Subsequently, as shown in FIG. 2B, over the surfaces of the sidewall insulator 35 and the gate insulator 31 is deposited a mask M1 composed of silicon nitride with a thickness of about 80 Å through a reduced pressure CVD process. Further over the mask M1 is deposited a mask M2 composed of polysilicon with a thickness of about 150 Å.

Next, as shown in FIG. 2C, ions of BF₂ are implanted into the mask M2 at an irradiation angle of 10 degrees (from the storage node electrode 22 toward the bit line contact 51) at an impurity does of 1E×10¹⁵ cm⁻². Subsequently, as shown in FIG. 2D, an alkaline solution is used to selectively etch the mask M2 in the region not subjected to the ion implantation of BF₂.

Thereafter, as shown in FIG. 3A, the remaining mask M2 is used as a mask member to etch the mask M1 with a hot phosphorous acid. Next, as shown in FIG. 3B, a chemical dray etching (CDE) is applied to remove the mask M2 by anisotropic etching.

Next, as shown in FIG. 3C, dry RTO is applied for 100 Å oxidation to selectively oxidize the region not covered in the mask M1 composed of silicon nitride to form the thick portion 35A. Finally, as shown in FIG. 3D, a hot phosphorous acid is used to peel off the mask M1 to complete the sidewall insulator 35 as shown in FIG. 1. Although not shown in FIG. 1, a spacer film of silicon nitride is deposited on the sidewall insulator 35 and a barrier layer of silicon nitride is further deposited thereon.

The above description is given to the steps of increasing the thickness of the sidewall insulator 35 close to the storage node electrode 22. The present invention is, though, not limited to the semiconductor device manufactured through those steps. For example, the present invention is also applicable to production of the same structure with the steps of increasing the thickness of the sidewall insulator 35 close to the bit line contact 51.

### Second Embodiment

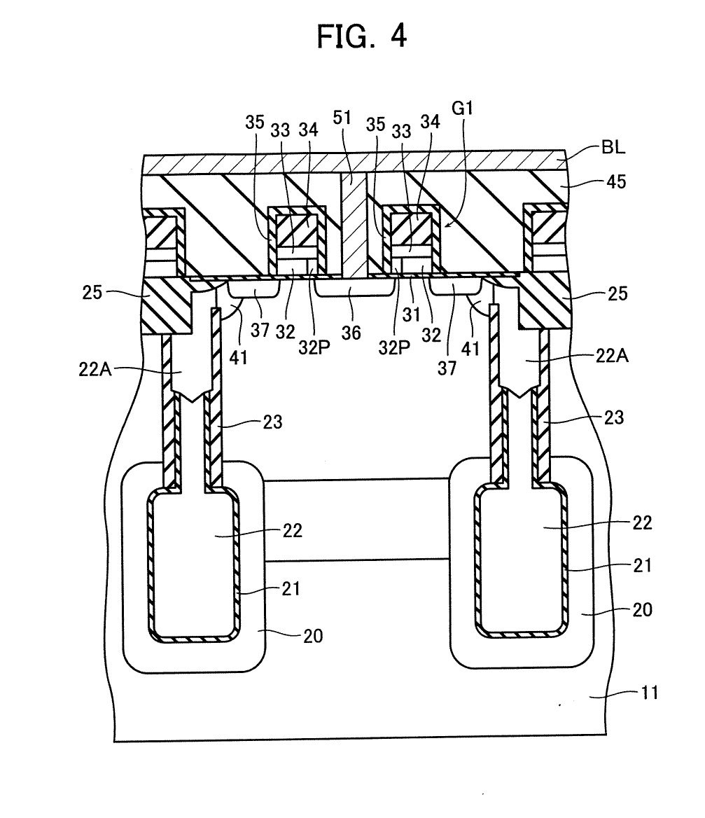

A DRAM according to a second embodiment of the present invention is described next with reference to FIG. 4. FIG. 4 shows a cross-sectional view of a memory cell in the DRAM according to this embodiment. The memory cell of this embodiment is also of the trench capacitor type like in the first embodiment. The same elements as those in the first embodiment are denoted with the same reference numerals in FIG. 4 and omitted from the following detailed description.

The second embodiment is different from the first embodiment in that the sidewall insulator 35 is controlled to have the same thickness on the side close to the bit line contact 51 and the side close to the storage node electrode 22. The polysilicon layer 32 contained in the gate electrode G1 includes a p-type layer 32P close to the bit line contact 51 and n-type other portions, different from the first embodiment. This embodiment is same as the first embodiment in that the cell transistor has a lower threshold on data write while the cell transistor has a higher threshold on “1” data holding. Thus, the data write property and the data holding property can be improved at the same time.

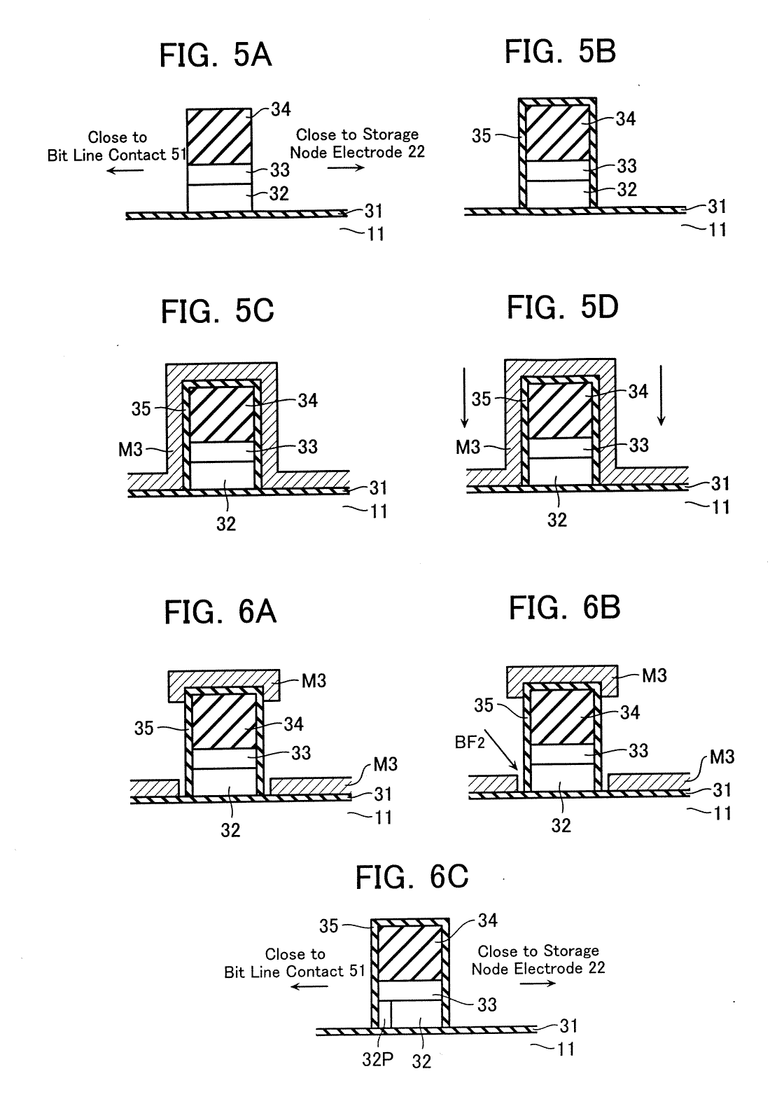

A procedure for formation of such the polysilicon layer 35 is described next with reference to FIGS. 5A-5D and FIGS. 6A-6C.

First, the gate electrode G1 is processed as shown in FIG. 5A. Then, wet RTO (Rapid Thermal Oxidation) with a mixed gas of hydrogen and oxygen is applied under a low pressure to oxidize the sidewall of the gate electrode G1 at a thickness of 40 Å to form the sidewall insulator 35 as shown in FIG. 5B.

Subsequently, as shown in FIG. 5C, over the sidewall insulator 35 and the gate insulator 31 is deposited a mask M3 composed of polysilicon with a thickness of about 300 Å through a reduced pressure CVD process.

Next, as shown in FIG. 5D, ion implantation of BF₂ is executed at an irradiation angle of 0 degree (normal) under the conditions including an acceleration voltage of 5 keV and an impurity does of 1E×10 cm⁻¹. As the irradiation angle is 0 degree, the portion of the mask M3 along the sidewall of the gate electrode G1 is not subjected to the ion implantation.

Thereafter, as shown in FIG. 6A, an alkaline solution is used to selectively etch the region of the mask M3 not subjected to the ion implantation of BF₂. In a word, only the mask M3 along the sidewall of the gate electrode G1 is removed.

Next, as shown in FIG. 6B, the remaining polysilicon mask M3 is used as a mask to implant BF₂ ions into the polysilicon layer 32 in the gate electrode G1 in a slanting direction (from the bit line contact 51 toward the storage node electrode 22) at an impurity does of 1×10¹⁵ cm⁻². As a result, the portion of the polysilicon layer 32 close to the bit line contact 51 can be turned into the p-type layer 32P as shown in FIG. 6C.

The above description is given to an example of p-type ion implantation in a slanting direction to turn the n-type polysilicon layer 32 into the p-type layer 32P though the present invention is not limited to this example. For example, also in the step of implanting n-type ions into a p-type polysilicon layer 32 to turn a portion into an n-type layer while keeping the remainder as the p-type layer, the same structure and effect can be achieved.

### Third Embodiment

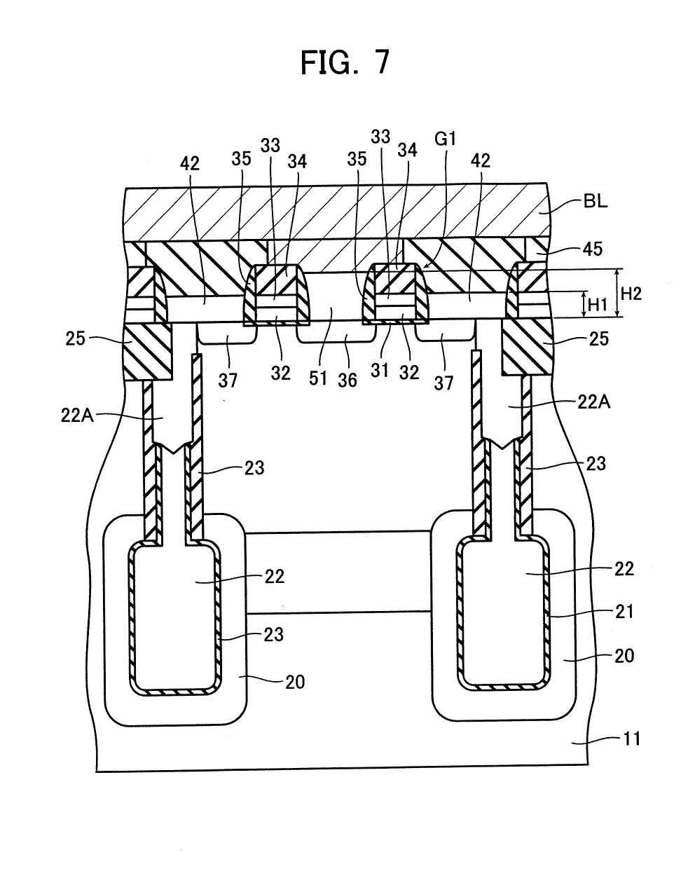

A DRAM according to a third embodiment of the present invention is described next with reference to FIG. 7. FIG. 7 shows a cross-sectional view of a memory cell in the DRAM according to this embodiment. The memory cell of this embodiment is also of the trench capacitor type like in the first embodiment. The same elements as those in the first and second embodiments are denoted with the same reference numerals in FIG. 7 and omitted from the following detailed description.

The third embodiment is same as the second embodiment in that the sidewall insulator 35 is controlled to have the same thickness on the side close to the bit line contact 51 and the side close to the storage node electrode 22. The polysilicon layer 32 is made n-type entirely. In this embodiment, however, the n-type diffusion layer 37 of the cell transistor is connected to the storage node electrode 22 via the polysilicon electrode 22A and a trench capacitor contact 42 formed on the surface of the semiconductor substrate 11. The trench capacitor contact 42 has a height from the surface of the semiconductor substrate 11, which is set at H1.

On the other hand, the bit line contact 51 has a height H2 from the surface of the semiconductor substrate 11, which is made sufficiently larger than H1 (H2>>H1). As in an instance where H2=1500 Å and H1=1000 Å, the former can be set around 1.5 times the magnitude of the latter. Thus, in this embodiment, like the preceding embodiments, the cell transistor has a lower threshold on data write while the cell transistor has a higher threshold on “1” data holding. Accordingly, the data write property and the data holding property can be improved at the same time. In this embodiment the sidewall insulator 35 is formed of silicon nitride.

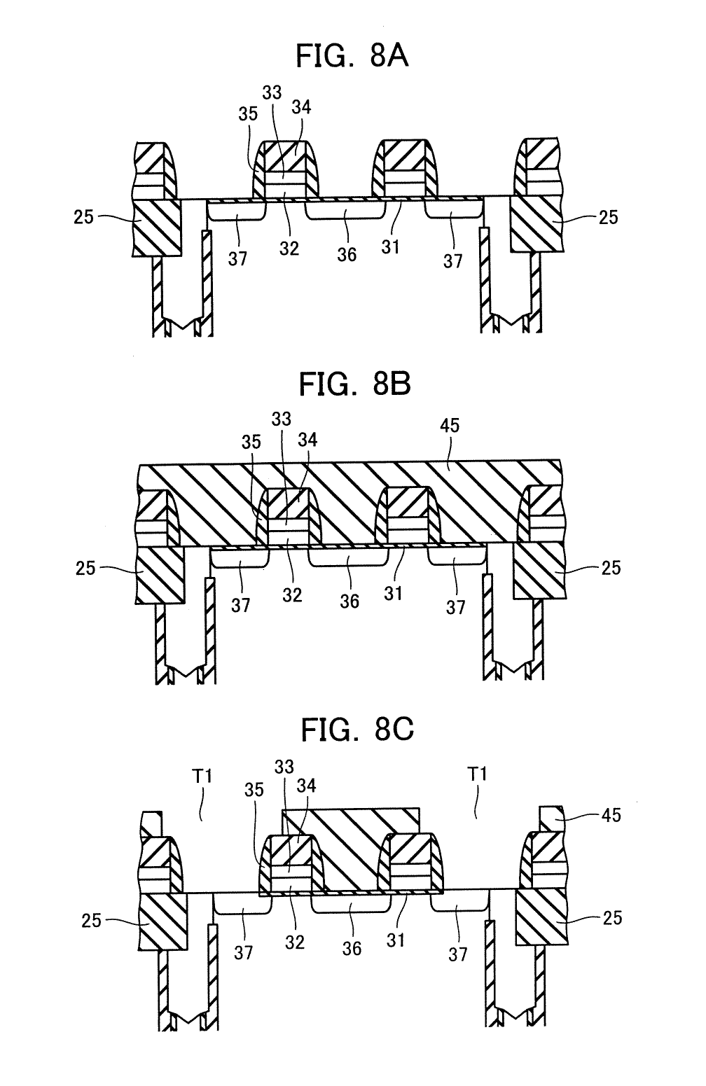

A procedure for formation of such the trench capacitor contact 42 and the bit line contact 51 is described next with reference to FIGS. 8A-8C, FIGS. 9A-9C and FIGS. 10A-10C.

After processing the gate electrode G1, RTO is applied for post-oxidation. A silicon nitride is then deposited over the entire surface of the semiconductor substrate 11 and etched back by dry etching to form the sidewall insulator 35 composed o silicon nitride (FIG. 8A).

Next, an interlayer insulator 45 of BPSG film is deposited over the entire surface as shown in FIG. 8B and then chemical mechanical polishing (CMP) is used to planarize the interlayer insulator 45. Then, as shown in FIG. 8C, photolithography is applied to form a contact hole pattern for use in formation of the trench capacitor contact 42 or the contact close to the storage node electrode 22. A mask of resist is used to process the interlayer insulator 45 by dry etching to form a contact hole T1. After formation of the contact hole T1, the gate insulator 31 exposed is peeled off through a process of RIE or the like.

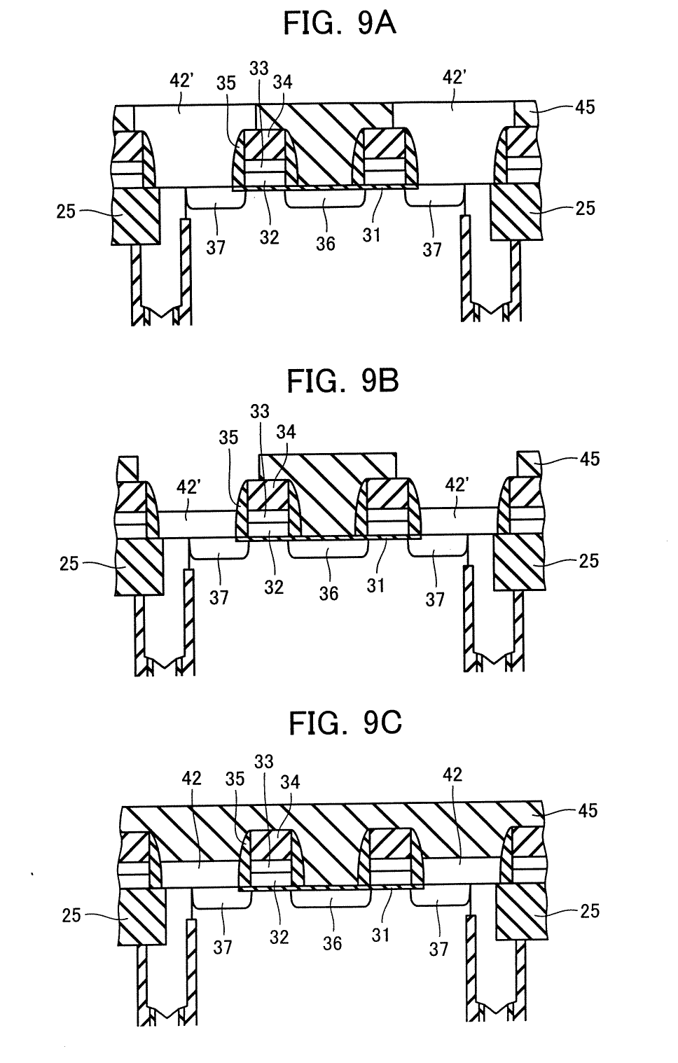

Next, a reduced pressure CVD process is employed to deposit a polysilicon film 42′ at a thickness of 200 Å, followed by flowing of PH₃ in the reduced pressure CVD equipment such that the polysilicon film 51 adsorbs P (phosphorous). Then, a polysilicon film 42′ is deposited again at a thickness of 2000 Å (FIG. 9A).

Next, as shown in FIG. 9B, chemical dry etching is applied to etch back the polysilicon film 42′ such that the polysilicon film 42′ with a thickness of 1000 Å remains only in the contact hole T1. Next, as shown in FIG. 9C, an interlayer insulator 45 is deposited again and then planarized through a CMP process.

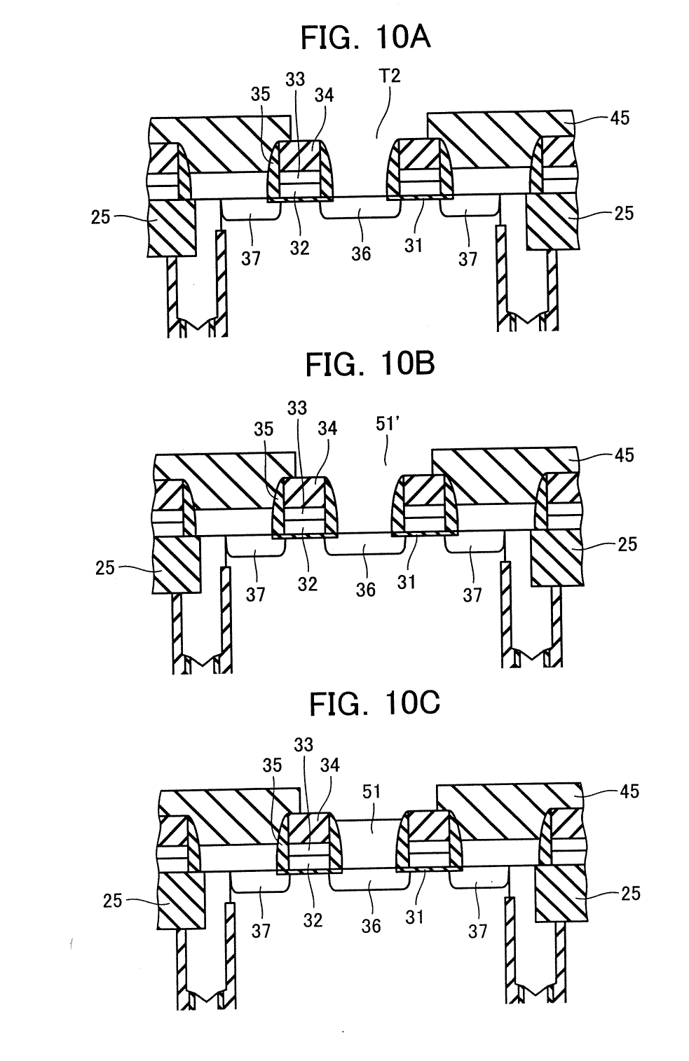

Subsequently, as shown in FIG. 10A, photolithography is used to form a contact hole pattern for use in formation of the bit line contact 51. A mask of resist is used to process the interlayer insulator 45 by dry etching to form a contact hole T2. After formation of the contact hole T2, the gate insulator 31 exposed is peeled off through a process of RIE or the like.

Next, a reduced pressure CVD process is employed to deposit a polysilicon film 51′ at a thickness of 100 Å, followed by flowing of PH₃ in the reduced pressure CVD equipment such that the polysilicon film 51′ adsorbs P (phosphorous). Then, deposition of a polysilicon film 51′ is started again to form a deposition with a thickness of 2000 Å.

Next, as shown in FIG. 10B, chemical dry etching is applied to etch the polysilicon film 51′ such that the polysilicon film 51′ with a thickness of 1500 Å remains only in the contact hole T2. Finally, as shown in FIG. 10C, a thermal process by RTA is applied at 950 degrees for 10 seconds to diffuse P (phosphorous) into the polysilicon film 51′ and activate it. Subsequently, the bit line contact 51 and the bit line BL are wired to complete the DRAM as shown in FIG. 7.

Thus, the impurity concentration in the trench capacitor contact 42 close to the storage node electrode 22 can be set lower than the impurity concentration in the bit line contact 51. A variation in distance from the phosphorous-adsorbed layer to the semiconductor substrate causes the bit line contact 51 and the trench capacitor contact 42 to have different amounts of diffused phosphorous (P). In a resultant structure, the depth of the diffusion layer can be made shallower in the trench capacitor contact 42 and deeper in the bit line contact 51. Thus, the cell transistor has a lower threshold on data write while the cell transistor has a higher threshold on “1” data holding. Accordingly, the data write property and the data holding property can be improved at the same time.

The above description is given to the process steps in the third embodiment though the structure of FIG. 7 is obtained not only through these process steps but can be modified variously.

### Fourth Embodiment

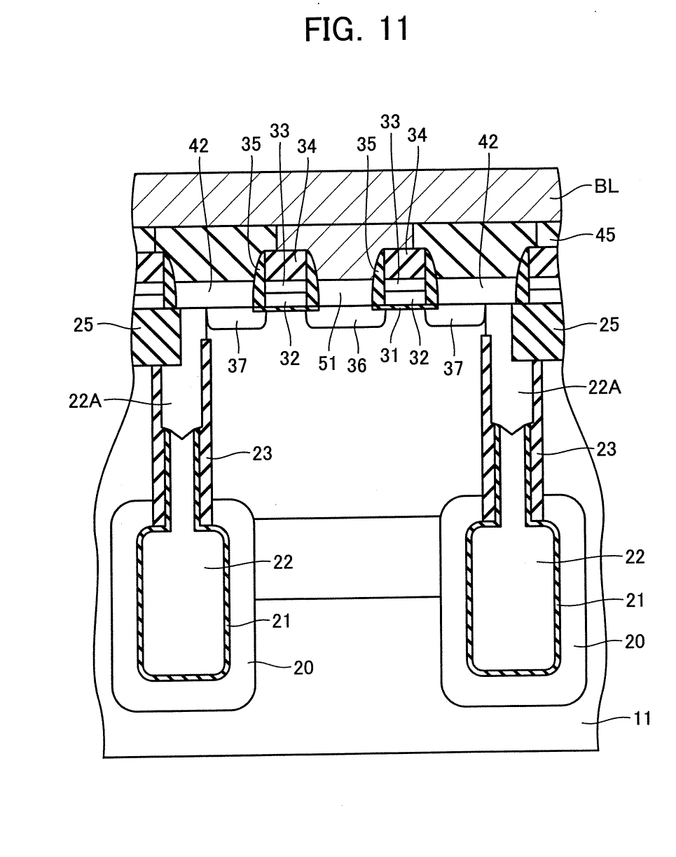

A DRAM according to a fourth embodiment of the present invention is described next with reference to FIG. 11. FIG. 11 shows a cross-sectional view of a memory cell in the DRAM according to this embodiment. The memory cell of this embodiment is also of the trench capacitor type like in the first embodiment. The same elements as those in the first and second embodiments are denoted with the same reference numerals in FIG. 11 and omitted from the following detailed description.

In this embodiment, the bit line contact 51 has a height H2 from the surface of the semiconductor substrate 11, which is made almost same as H1. On the other hand, the impurity concentration Db in the bit line contact 51 is made higher than the impurity concentration Da in the trench capacitor contact 42, different from the third embodiment. For example, Db may be designed to have a magnitude about 1.5 times Da, thereby exerting the same effect as in the third embodiment.

### [Others]

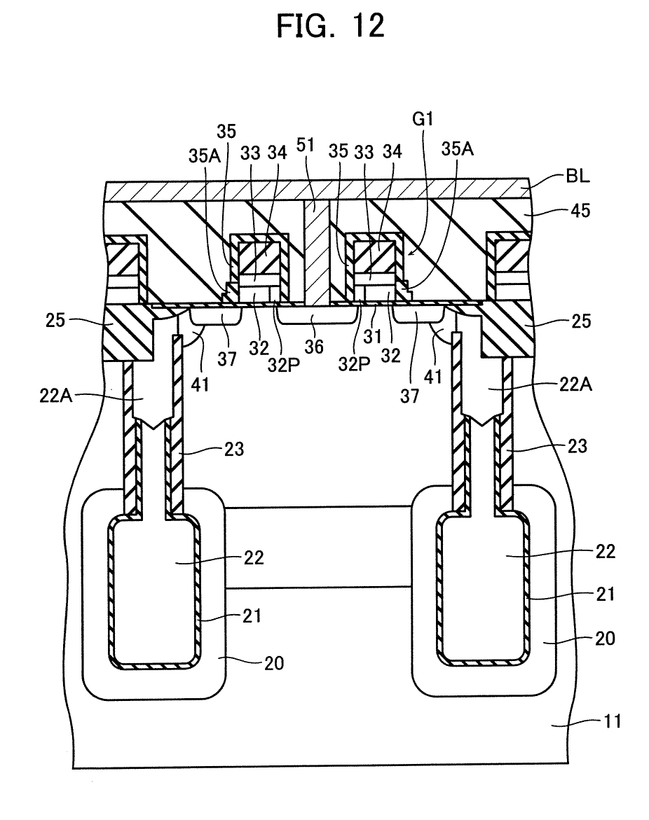

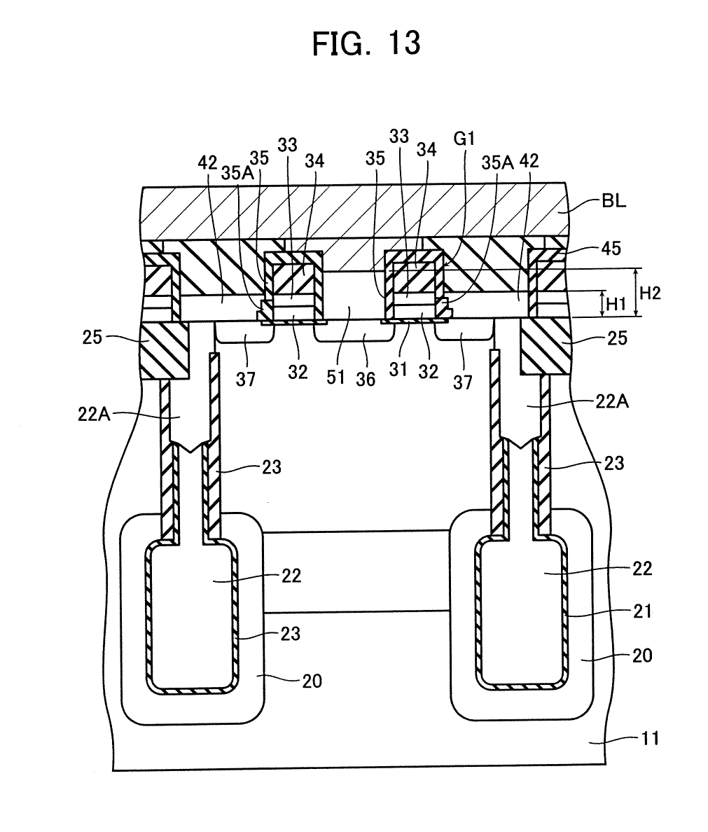

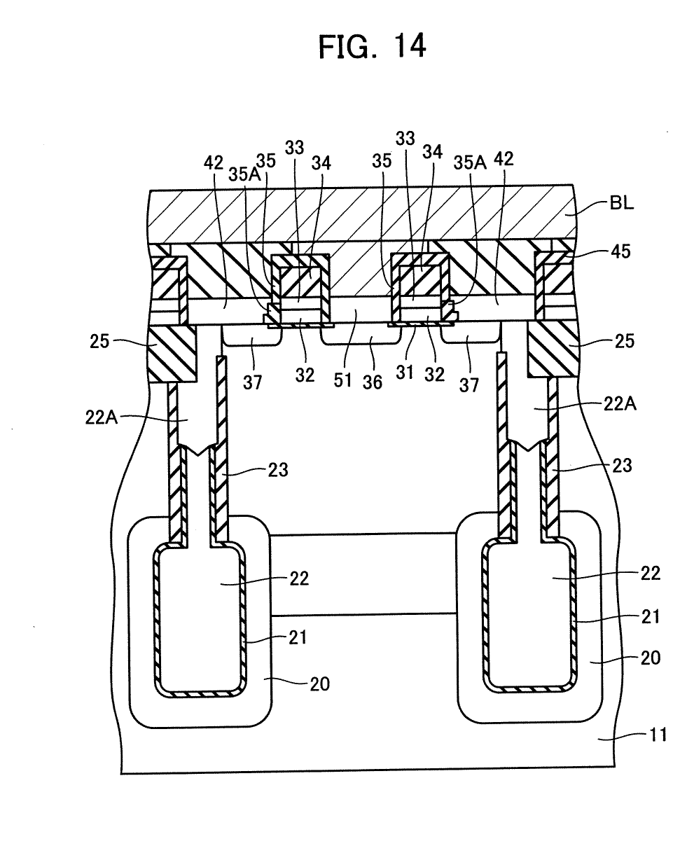

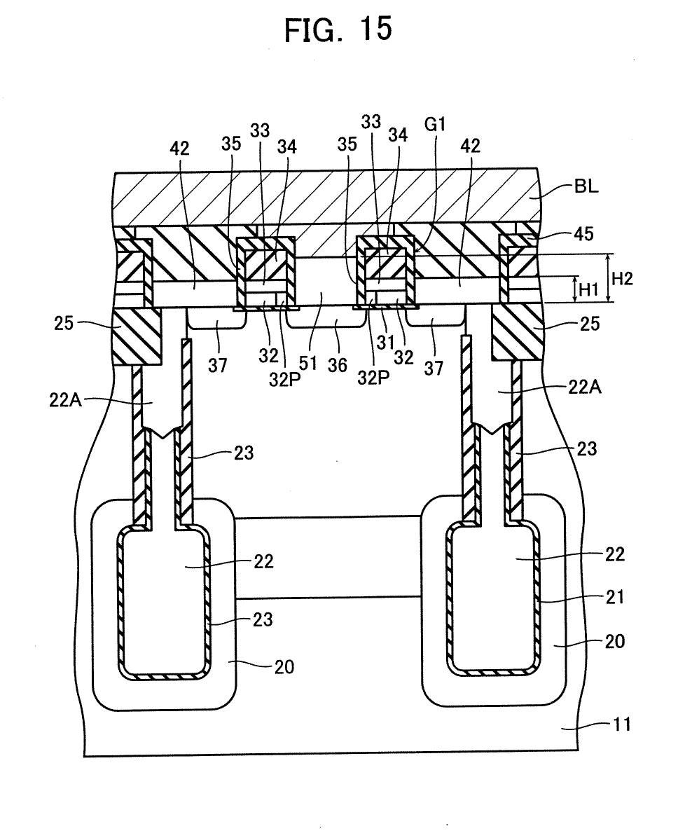

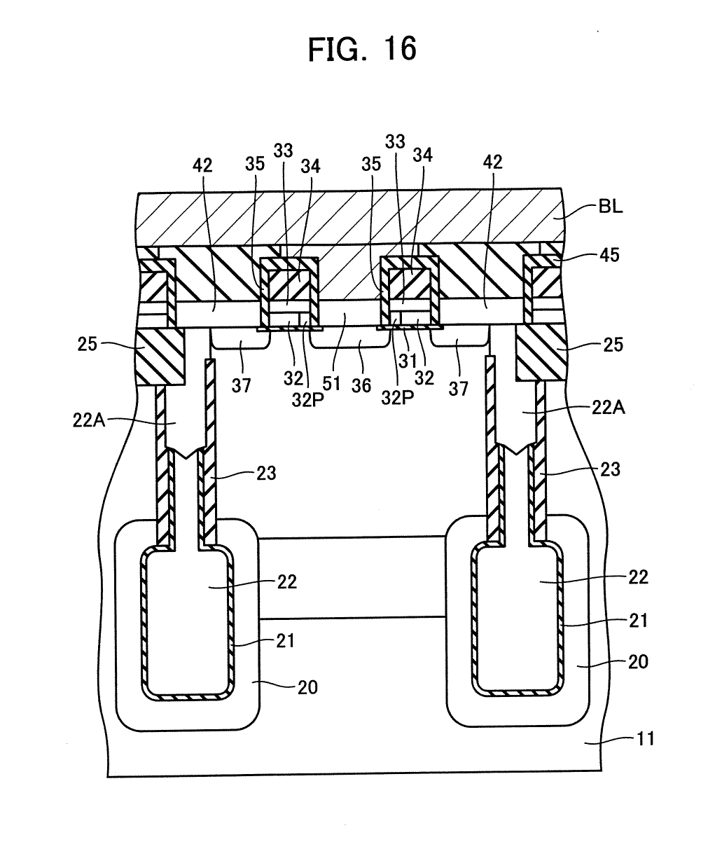

The embodiments of the invention have been described above though the present invention is not limited to these embodiments but rather can be given various alternations and additions without departing from the scope of the invention. For example, the above embodiments exemplify the first conduction type as the n-type and the second conduction type as the p-type. The present invention is, though, also applicable to an example in which the first conduction type is the p-type and the second conduction type is the n-type. As shown in FIG. 12-16, a device that includes the features of the above embodiments in combination is also contained in the scope of the present invention, needless to say. The DRAM described in the above embodiments is of the type that two memory cells share a bit line contact. The present invention is not limited to such the DRAM but also applicable to a DRAM of the type that a bit line contact is provided per memory cell.

What is claimed is:

1. A semiconductor memory device, comprising:
a MOSFET formed in the surface of a semiconductor substrate; and
a trench capacitor provided in a trench formed in the surface of the semiconductor substrate, the MOSFET including
a gate electrode formed on a gate insulator in the surface of the semiconductor substrate,
a sidewall insulator formed on a sidewall of the gate electrode,
a first and a second diffusion layer formed on the surface of the semiconductor substrate sandwiching the gate electrode,
a trench capacitor contact formed to connect the first diffusion layer to the trench capacitor, and
a bit line contact formed to connect the second diffusion layer to a bit line,
wherein the sidewall insulator close to the first diffusion layer is formed thicker than the sidewall insulator close to the second diffusion layer.

2. The semiconductor memory device according to claim 1, wherein the gate electrode is formed of polysilicon and having a portion of the first conduction type close to the second diffusion layer and other portions of the second conduction type.

3. The semiconductor memory device according to claim 1, wherein the trench capacitor contact is formed on the surface of the semiconductor substrate, and the bit line contact is formed of polysilicon having an impurity concentration made higher than the impurity concentration of polysilicon forming the trench capacitor contact.

4. The semiconductor memory device according to claim 1, wherein the trench capacitor contact is formed on the surface of the semiconductor substrate, and the bit line contact is formed of polysilicon having a height made higher than a height of polysilicon forming the trench capacitor contact.

5. A semiconductor memory device, comprising:
a MOSFET formed in the surface of a semiconductor substrate; and
a trench capacitor provided in a trench formed in the surface of the semiconductor substrate, the MOSFET including
a gate electrode formed on a gate insulator in the surface of the semiconductor substrate,
a sidewall insulator formed on a sidewall of the gate electrode,
a first and a second diffusion layer formed on the surface of the semiconductor substrate sandwiching the gate electrode,
a trench capacitor contact formed on the surface of the semiconductor substrate to connect the first diffusion layer to the trench capacitor, and
a bit line contact connected to the second diffusion layer,
wherein the bit line contact is formed of polysilicon having an impurity concentration made higher than the impurity concentration of polysilicon forming the trench capacitor contact.

6. The semiconductor memory device according to claim 5, wherein the gate electrode is formed of polysilicon and having a portion of the first conduction type close to the second diffusion layer and other portions of the second conduction type.

7. The semiconductor memory device according to claim 5, wherein the bit line contact is formed of polysilicon having a height made higher than a height of polysilicon forming the trench capacitor contact.

8. A semiconductor memory device, comprising:
a MOSFET formed in the surface of a semiconductor substrate; and
a trench capacitor provided in a trench formed in the surface of the semiconductor substrate, the MOSFET including
a gate electrode formed on a gate insulator in the surface of the semiconductor substrate,
a sidewall insulator formed on a sidewall of the gate electrode,
a first and a second diffusion layer formed on the surface of the semiconductor substrate sandwiching the gate electrode,
a trench capacitor contact formed on the surface of the semiconductor substrate to connect the first diffusion layer to the trench capacitor, and
a bit line contact connected to the second diffusion layer,
wherein the bit line contact is formed of polysilicon having a height made higher than the height of polysilicon forming the trench capacitor contact.

9. The semiconductor memory device according to claim 8, wherein the gate electrode is formed of polysilicon and having a portion of the first conduction type close to the second diffusion layer and other portions of the second conduction type.
